(19) United States
(12) Patent Application Publication
(10) Pub. No.: US 2017/0315179 A1
(43) Pub. Date: Nov. 2, 2017

(54) PARAMETER ESTIMATION DEVICE FOR BATTERY

(71) Applicants: CALSONIC KANSEI CORPORATION, Saitama-shi, Saitama (JP); KEIO UNIVERSITY, Minato-ku, Tokyo (JP)

(72) Inventors: Atsushi BABA, Saitama-shi, Saitama (JP); Shuichi ADACHI, Minato-ku, Tokyo (JP)

(73) Assignees: CALSONIC KANSEI CORPORATION, Saitama-shi, Saitama (JP); KEIO UNIVERSITY, Minato-ku, Tokyo (JP)

(21) Appl. No.: 15/520,522

(22) PCT Filed: Oct. 26, 2015
(86) PCT No.: PCT/JP2015/005365

§ 371 Date: Apr. 20, 2017

(30) Foreign Application Priority Data
Oct. 31, 2014 (JP) 2014-223124

(51) Int. Cl. G01R 31/36

(52) U.S. Cl. CPC G01R 31/3651; G01R 31/3662; G01R 31/3675

(57) ABSTRACT

A parameter estimation device for a battery capable of reducing an error in estimate of an internal resistance caused by a temperature difference is provided. In a parameter estimation device for a battery (1) for sequentially estimating parameters including a resistance in an equivalent circuit model (41) of the battery based on a temperature of the battery and at least one of a voltage of the battery and a current of the battery, as a resistance value of the resistance in the equivalent circuit model of the battery, a resistance value at a predetermined temperature is estimated, and a resistance value at a present temperature is calculated based on the resistance value at the predetermined temperature and the present temperature.

### CROSS REFERENCE TO RELATED APPLICATION

This application claims priority to Japanese Patent Application No. 2014-223124 filed on Oct. 31, 2014, the entire disclosure of which is incorporated herein by reference.

### TECHNICAL FIELD

The disclosure relates to a parameter estimation device for a battery capable of sequentially estimating parameters of an equivalent circuit model of the battery by Kalman filtering.

### BACKGROUND

A conventional battery internal state/parameter estimation device described in Patent Literature (PTL) 1 is known as an example. This conventional battery parameter estimation device detects the charge and discharge current and terminal voltage of a battery and, with these values as input, estimates (calculates) the parameters of the battery and the internal state quantity and open circuit voltage value of the battery by Kalman filtering using an equivalent circuit model of the battery including a resistance.

### CITATION LIST

### Patent Literatures

PTL 1: JP 2014-74682 A

### SUMMARY

### Technical Problem

However, in the aforementioned equivalent circuit model of the battery, the temperature of the battery, which is a factor significantly affecting the internal resistance of the battery, is not taken into account. This causes a large estimation error of the internal resistance of the battery. In detail, in the case where the last estimation result in the previous estimation is used as an initial value in the present estimation upon starting battery state estimation, there is a possibility that the temperature of the battery has changed from when the battery state was estimated last in the previous estimation. In this case, estimation is started with such an initial value that is far from a value to be estimated in the present estimation, and it takes time for the estimation result to correspond to the present temperature (i.e. converge). Thus, not using information of the temperature of the battery leads to poor SOC estimation accuracy.

It could be helpful to provide a parameter estimation device for a battery capable of reducing an error in estimate of an internal resistance of the battery caused by a temperature difference and estimating parameters more quickly and accurately.

### Solution to Problem

A parameter estimation device for a battery according to a first aspect is a parameter estimation device for a battery for sequentially estimating parameters including a resistance in an equivalent circuit model of the battery based on a temperature of the battery and at least one of a voltage of the battery and a current of the battery, wherein as a resistance value of the resistance in the equivalent circuit model of the battery, a resistance value R^{T0} at a predetermined temperature T₀ is estimated, and a resistance value at a present temperature is calculated based on the resistance value at the predetermined temperature and the present temperature.

A parameter estimation device for a battery according to a second aspect is the parameter estimation device for a battery wherein the resistance value at the present temperature is calculated using the following expression that includes the resistance value at the predetermined temperature and a temperature-dependent coefficient:

$$R ( T ) = {R}^{{T}_{0}} exp ( \frac{{a}_{R} ( T - {T}_{0} )}{{T}_{0} T} ) \qquad [ Math . 1 ]$$

where T is the present temperature, R(T) is the resistance value at the present temperature T, T₀ is the predetermined temperature, R^{T0} is the resistance value at the predetermined temperature T₀, and a_{R} is the temperature-dependent coefficient.

A parameter estimation device for a battery according to a third aspect is the parameter estimation device for a battery wherein the temperature-dependent coefficient a_{R} is a constant obtained beforehand.

A parameter estimation device for a battery according to a fourth aspect is the parameter estimation device for a battery wherein the temperature-dependent coefficient a_{R} is determined based on a table obtained beforehand and indicating a relationship between the temperature-dependent coefficient a_{R} and the temperature T.

A parameter estimation device for a battery according to a fifth aspect is the parameter estimation device for a battery wherein the temperature-dependent coefficient a_{R} and the resistance value R^{T0} at the predetermined temperature T₀ are obtained by simultaneous estimation.

### Advantageous Effect

The parameter estimation device for a battery according to the first aspect can reduce an error in estimate of an internal resistance caused by a temperature difference, and estimate parameters more quickly and accurately.

The parameter estimation device for a battery according to the second aspect can reduce an error in estimate of an internal resistance caused by a temperature difference, and estimate parameters more quickly and accurately.

The parameter estimation device for a battery according to the third aspect can improve estimation accuracy using temperature information, while limiting the number of parameters to be estimated to that of a conventional model.

The parameter estimation device for a battery according to the fourth aspect can estimate parameters more quickly and accurately using the temperature-dependent coefficient a_{R} corresponding to the temperature, in the case where the rate-determining process changes at some temperature.

The parameter estimation device for a battery according to the fifth aspect can estimate parameters more quickly and accurately even in the case where the temperature-dependent coefficient changes due to battery degradation or the like.

### BRIEF DESCRIPTION OF THE DRAWINGS

In the accompanying drawings:

FIG. 1 is a functional block diagram of a parameter estimation device for a battery according to one of the disclosed embodiments, which is connected to the battery;

FIG. 2 is a diagram for explaining an equivalent circuit model of the battery;

FIG. 3 is a diagram illustrating the relationship between the open circuit voltage and state of charge of the battery;

FIG. 4 is a diagram illustrating an nth-order Foster-type RC ladder circuit approximating Warburg impedance;

FIG. 5 is a diagram illustrating a battery equivalent circuit in the case of approximation by a tertiary Foster-type circuit;

FIG. 6A is a graph illustrating the relationship between the temperature of the battery and the internal resistance (direct resistance) of the battery;

FIG. 6B is a graph illustrating the relationship between the temperature of the battery and the internal resistance (diffusion resistance) of the battery;

FIG. 7 is a graph illustrating the estimation error in the case of performing simultaneous estimation with a model of Example 1;

FIG. 8A is an Arrhenius plot illustrating the relationship between the internal resistance and temperature of the battery (in the case where there is one rate-determining process);

FIG. 8B is an Arrhenius plot illustrating the relationship between the internal resistance and temperature of the battery (in the case where there are two rate-determining processes);

FIG. 9 is a table illustrating the relationship between temperature and a temperature-dependent coefficient; and

FIG. 10 is a graph illustrating the estimation error in the case of performing simultaneous estimation with a model of Example 3.

### DETAILED DESCRIPTION

The following describes one of the disclosed embodiments in detail, with reference to drawings.

### Embodiment

A parameter estimation device for a battery according to this embodiment is used in a vehicle such as an electric vehicle or a hybrid electric vehicle. The vehicle includes an electric motor for driving the vehicle, a battery, controllers for these components, etc., and the power supply (discharge) to the electric motor, the regeneration of braking energy from the electric motor during braking, and the power recovery (charge) from a ground charging facility to the battery are performed. Such charge and discharge current entering and leaving the battery changes the internal state of the battery. By monitoring the internal state while estimating the internal state using the parameter estimation device for a battery, necessary information such as remaining battery level is collected.

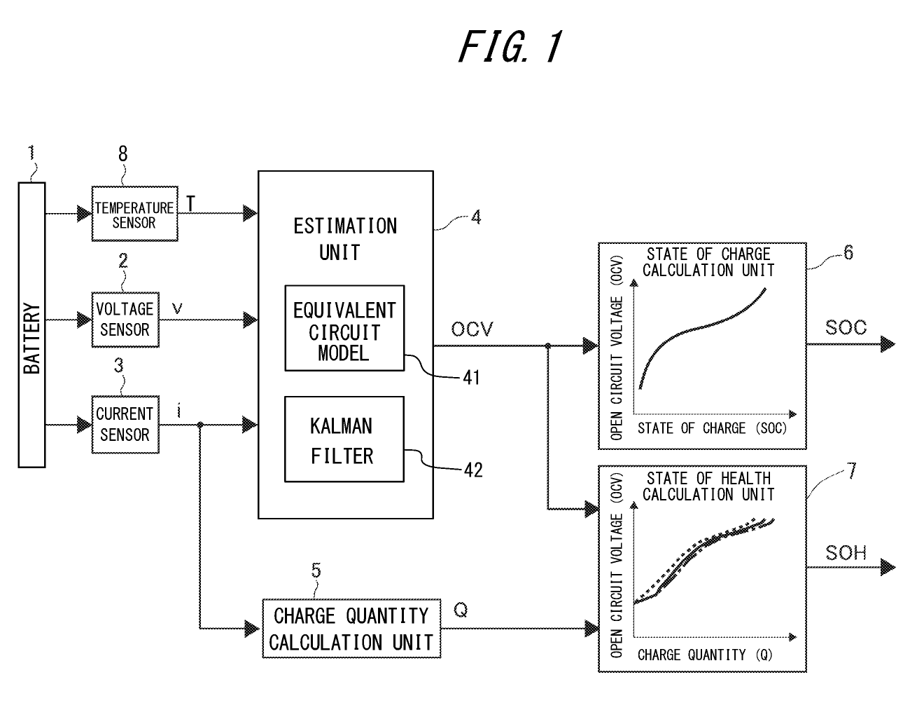

As illustrated in FIG. 1, a parameter estimation device for a battery 1 includes a voltage sensor (terminal voltage detection unit) 2, a current sensor (charge and discharge current detection unit) 3, a temperature sensor (battery temperature detection unit) 8, an estimation unit 4, a charge quantity calculation unit 5, a state of charge calculation unit 6, and a state of health calculation unit 7. The estimation unit 4, the charge quantity calculation unit 5, the state of charge calculation unit 6, and the state of health calculation unit 7 are realized by, for example, an in-vehicle microcomputer.

The battery 1 is, for example, a rechargeable battery (secondary battery). Although this embodiment describes the case where the battery 1 is a lithium ion battery, other types of battery may be used.

The terminal voltage detection unit 2 is, for example, a voltage sensor, and detects the terminal voltage value v of the battery 1. The terminal voltage detection unit 2 supplies the detected terminal voltage value v to the estimation unit 4.

The charge and discharge current detection unit 3 is, for example, a current sensor, and detects the charge and discharge current value i of the battery 1. The charge and discharge current detection unit 3 supplies the detected charge and discharge current value i to the estimation unit 4.

The battery temperature detection unit 8 is, for example, a temperature sensor, and detects the temperature T of the battery 1. The battery temperature detection unit 8 supplies the detected temperature T to the estimation unit 4.

The estimation unit 4 includes a battery equivalent circuit model 41 of the battery 1, and a Kalman filter 42. The estimation unit 4 is capable of estimating (calculating) the parameter values of the battery equivalent circuit model 41, the open circuit voltage OCV of the battery 1, and the internal state quantity of the battery 1 using the Kalman filter 42. In this embodiment, the estimation unit 4 simultaneously estimates the parameter values and the internal state quantity based on the terminal voltage v from the terminal voltage detection unit 2 and the charge and discharge current i from the charge and discharge current detection unit 3, and calculates the open circuit voltage OCV based on the estimated parameter values. The estimation and calculation process performed by the estimation unit 4 will be described in detail later. The estimation unit 4 supplies the calculated open circuit voltage OCV to the state of charge calculation unit 6 and the state of health calculation unit 7.

The battery equivalent circuit model 41 is realized by, for example, a Foster-type RC ladder circuit in which parallel circuits of a resistor and a capacitor are connected and that is represented by approximation by an infinite series sum, or a Cowell-type RC ladder circuit in which series-connected resistors are grounded with a capacitor and that is represented by approximation by a continued fraction expansion. Such resistor and capacitor are included in the parameters of the battery equivalent circuit model 41.

The Kalman filter 42 designs a model (the battery equivalent circuit model 41 in this embodiment) of a target system, supplies the same input signal to the model and the actual system, and compares their respective outputs. If there is an error between the outputs, the Kalman filter 42 multiplies the error by the Kalman gain and feeds it back to the model, thus correcting the model so as to minimize the error. The Kalman filter 42 repeatedly performs this process to estimate the parameters of the model.

The charge quantity calculation unit 5 receives the charge and discharge current value i of the battery 1 detected by the charge and discharge current detection unit 3, and sequentially integrates the received value to calculate the quantity of charge entering and leaving the battery 1. The charge quantity calculation unit 5 subtracts the entering and leaving charge quantity from the remaining charge quantity stored before the sequentially integration, to calculate the present charge quantity Q of the battery 1. The charge quantity Q is output to the state of health calculation unit 7.

The state of charge calculation unit 6 stores, for example as a characteristic table, relational data obtained by determining the relationship between the open circuit voltage value and the state of charge by experiment or the like beforehand, given that their relationship is unlikely to be affected by temperature, degradation of the battery 1, etc. Based on this characteristic table, the state of charge calculation unit 6 estimates the present state of charge SOC from the open circuit voltage estimate obtained by the estimation unit 4. The state of charge SOC is used for battery management of the battery 1.

The state of health calculation unit 7 has a characteristic table indicating the relationship between the charge quantity Q and the open circuit voltage OCV for each range of state of health SOH divided by a predetermined width. This characteristic table is, for example, disclosed in JP 2012-57956 A by the applicant of this application. The state of health calculation unit 7 receives the open circuit voltage OCV estimated by the estimation unit 4 and the charge quantity Q calculated by the charge quantity calculation unit 5, calculates which range of state of health SOH in the characteristic table the received values belong to, and outputs the state of health SOH that applies.

The equivalent circuit model 41 of the battery 1 is described below. Typically, the electrode reaction of a battery involves a charge transfer process in the interface between an electrolytic solution and an active material and an ion diffusion process in the electrolytic solution or the active material. In a physical process (non-Faradaic process) battery such as a lithium ion battery, that is, a battery in which the diffusion phenomenon is dominant, the effect of Warburg impedance which is the impedance resulting from the diffusion process is dominant.

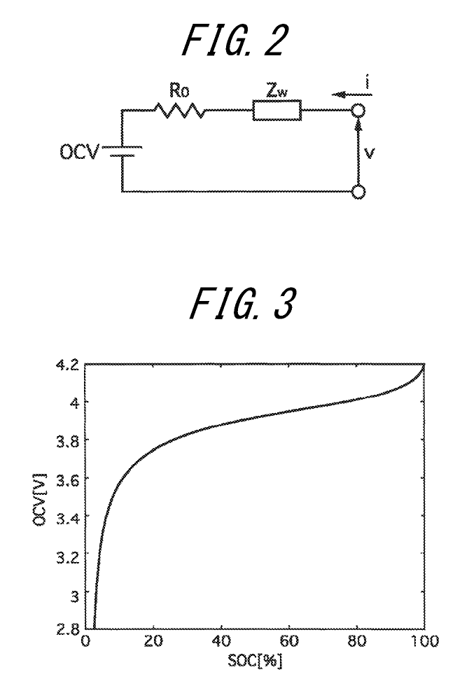

First, suppose the model of the battery is an open circuit that has the open circuit voltage OCV and in which internal resistance R₀ and Warburg impedance Z_{w} are connected in series, as illustrated in FIG. 2.

The open circuit voltage OCV is the nonlinear function of the state of charge SOC, as illustrated in FIG. 3. The state of charge SOC is represented by Expression (1), using the charge and discharge current value i and full charge capacity FCC.

$$\begin{matrix}[ Math . 2 ] & \\ \frac{d}{dt} SOC = \frac{i}{FCC} . & ( 1 )\end{matrix}$$

The transfer function of the Warburg impedance Z_{w} is represented by Expression (2).

$$\begin{matrix}[ Math . 3 ] & \\ {Z}_{W} ( s ) = \frac{{R}_{d}}{\sqrt{{τ}_{d} s}} tanh \sqrt{{τ}_{d} s} & ( 2 )\end{matrix}$$

where s is a Laplace operator, and the diffusion resistance R_{d} is a low-frequency limit (ω→0) of Z_{w}(s). The diffusion time constant τ_{d} denotes the rate of the diffusion reaction. Using the diffusion resistance R_{d} and the diffusion time constant τ_{d}, diffusion capacitance C_{d} is defined by Expression (3).

$$\begin{matrix}[ Math . 4 ] & \\ {C}_{d} := \frac{{τ}_{d}}{{R}_{d}} . & ( 3 )\end{matrix}$$

Due to the presence of the square root of the Laplace operator s in Expression (2), it is difficult to directly convert the Warburg impedance Z_{w} into the time domain. Hence, consider approximating the Warburg impedance Z_{w}. For example, the Warburg impedance Z_{w} can be approximated by an infinite series sum or a continued fraction expansion.

Approximation by an infinite series sum is described below. The Warburg impedance Z_{w} can be represented as an infinite series sum as shown by Expression (4).

$$\begin{matrix}[ Math . 5 ] & \\ {Z}_{W} ( s ) = {\sum }_{n = 1}^{∞} \frac{{R}_{n}}{{sC}_{n} {R}_{n} + 1} & ( 4 )\end{matrix}$$

where

$$\begin{matrix}[ Math . 6 ] & \\ {C}_{n} = \frac{{C}_{d}}{2} & ( 5 ) \\ {R}_{n} = \frac{8 {R}_{d}}{{( 2 n - 1 )}^{2} {π}^{2}} . & ( 6 )\end{matrix}$$

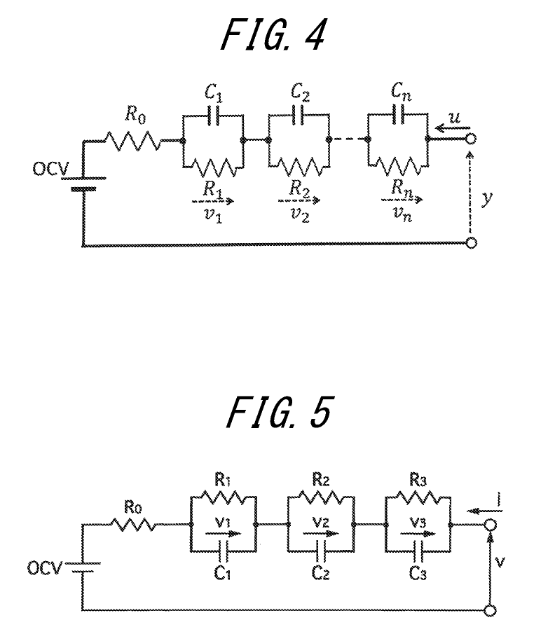

The aforementioned approximate expression is represented by a circuit diagram of an nth-order Foster-type circuit in which n parallel circuits of a resistor and a capacitor are connected in series (see FIG. 4). As is clear from Expressions (5) and (6), with the nth-order Foster-type equivalent circuit model approximating the Warburg impedance Z_{w}, the other parameters (resistor Rₙ, capacitor Cₙ) of the equivalent circuit can be calculated using the diffusion capacitance C_{d} and the diffusion resistance R_{d}.

The battery equivalent circuit model 41 in the case of approximation by a tertiary Foster-type circuit is described below (see FIG. 5). In the drawing, R is a resistor and C is a capacitor, with each subscript representing the corresponding order. Let x be a state variable, u be an input, and y be an output.

[Math. 7]

x=[SOC v₃ v₂ v₁]^{T} (7)

u=i (8)

y=v (9)

where v₁ to v₃ are each a voltage drop in the capacitor corresponding to the subscript, i is a current flowing through the whole circuit, and v is a voltage drop of the whole circuit. The superscript T of the matrix denotes its transposed matrix.

Then, the state space is

$$\begin{matrix}[ Math . 8 ] & \\ \dot{x} ( t ) = {F}_{f} x ( t ) + {G}_{f} u ( t ) & ( 10 ) \\ y ( t ) = {f}_{OCV} ( SOC ( t ) ) + {H}_{f} x ( t ) + {R}_{0} u ( t ) & ( 11 ) \\ {F}_{f} = diag ( 0 , - \frac{1}{{C}_{1} {R}_{1}} , … , - \frac{1}{{C}_{n} {R}_{n}} ) & ( 12 ) \\ {G}_{f} = {[ \begin{matrix}\frac{1}{FCC} & \frac{1}{{C}_{1}} & … & \frac{1}{{C}_{n}}\end{matrix} ]}^{T} & ( 13 ) \\ {H}_{f} = [ \begin{matrix}0 & 1 & … & 1\end{matrix} ] . & ( 14 )\end{matrix}$$

Here, Expression (10) is a state equation, and Expression (11) is an output equation.

There is a case where the resistance components (direct resistance R₀ and diffusion resistance R_{d}) in the model are constant regardless of temperature. In this embodiment, the resistance components (direct resistance R₀ and diffusion resistance R_{d}) in the model are treated as being temperature-dependent based on Arrhenius' equation (a formula for predicting the rate of a chemical reaction at a temperature).

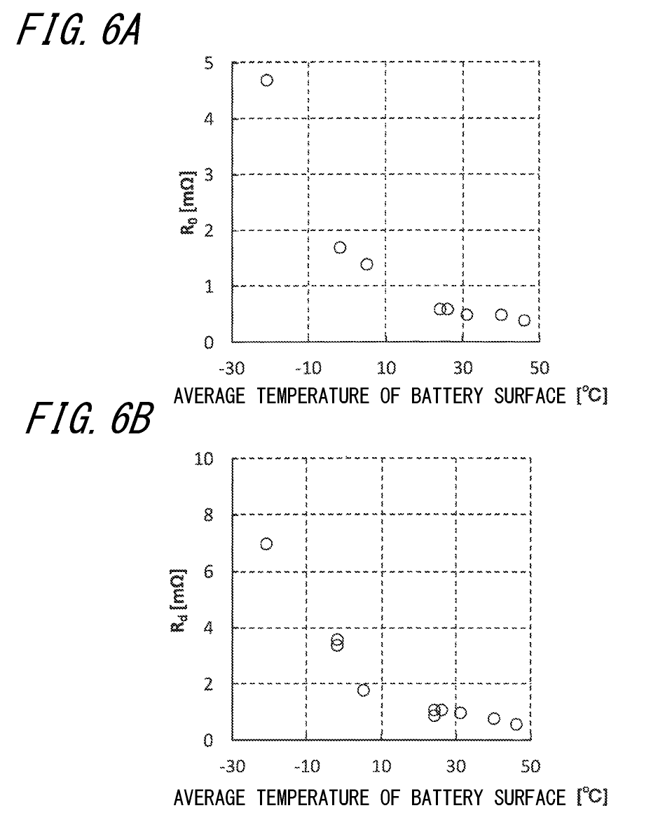

An expression indicating the temperature dependence of a resistance based on Arrhenius' equation is derived here. Battery characteristics are typically known to change depending on battery temperature. FIGS. 6A and 6B are each a diagram illustrating the relationship between the battery temperature (the average temperature of the battery surface) and the internal resistance of the battery when continuous-time system identification is applied to data for each temperature and estimating the internal resistance of the battery. As can be understood from the drawings, the direct resistance R₀ (FIG. 6A) and the diffusion resistance R_{d} (FIG. 6B) are each exponentially dependent on the battery temperature. Hence, the internal resistance R(T) of the battery is represented by Expression (15) according to Arrhenius' equation.

$$\begin{matrix}[ Math . 9 ] & \\ R ( T ) = A exp ( - \frac{{E}_{a}}{ T} ) \\ ( \text{:} gas constant ) . & ( 15 )\end{matrix}$$

In Expression (15), A is a frequency factor, Eₐ is activation energy, and T is the absolute temperature of the battery.

By substituting the frequency factor A by a resistance value R^{∞} at infinite temperature and substituting the ratio of the activation energy and the gas constant by a temperature-dependent coefficient a_{R}, Expression (15) is rewritten as Expression (16).

$$\begin{matrix}[ Math . 10 ] & \\ R ( T ) = {R}^{∞} exp ( - \frac{{a}_{R}}{T} ) . & ( 16 )\end{matrix}$$

Here, the resistance value R^{∞} at infinite temperature is an ideological reference value. As a reference value that can be easily obtained by experiment, a resistance value R^{T0} at a practical temperature T₀[K] is defined, to substitute for R^{∞}. Suppose T=T₀ in Expression (16). Then, Expression (17) is derived.

$$\begin{matrix}[ Math . 11 ] & \\ {R}^{{T}_{0}} = R ( {T}_{0} ) = {R}^{∞} exp ( - \frac{{a}_{R}}{{T}_{0}} ) . & ( 17 )\end{matrix}$$

Modifying Expression (17) yields Expression (18).

$$\begin{matrix}[ Math . 12 ] & \\ {R}^{∞} = {R}^{{T}_{0}} exp ( \frac{{a}_{R}}{{T}_{0}} ) . & ( 18 )\end{matrix}$$

Substituting Expression (18) into Expression (16) yields Expression (19).

$$\begin{matrix}[ Math . 13 ] & \\ R ( T ) = {R}^{{T}_{0}} exp ( \frac{{a}_{R} ( T - {T}_{0} )}{{T}_{0} T} ) . & ( 19 )\end{matrix}$$

Using Expression (19), the direct resistance R₀ and the diffusion resistance R_{d} are respectively represented by Expressions (20) and (21).

$$\begin{matrix}[ Math . 14 ] & \\ {R}_{0} ( T ) = {R}_{0}^{{T}_{0}} exp ( \frac{{a}_{R} ( T - {T}_{0} )}{{T}_{0} T} ) & ( 20 ) \\ {R}_{d} ( T ) = {R}_{d}^{{T}_{0}} exp ( \frac{{a}_{{R}_{d}} ( T - {T}_{0} )}{{T}_{0} T} ) & ( 21 )\end{matrix}$$

where R₀^{T0} and R_{d}^{T0} are respectively the resistance values of the resistors R₀ and R_{d} at the temperature T₀ [K], and a_{R0} and a_{R0} are respectively the temperature-dependent coefficients of the resistors R₀ and R_{d}. In this model, R₀^{To} and R_{d}^{T0} are estimated. Since the temperature T of the battery is measured by the temperature measurement unit 8, R₀ and R_{d} can be calculated respectively from the estimates of R₀^{T0} and R_{d}^{T0}. In this embodiment, a_{R0} and a_{R0} are constants.

As described above, the parameter estimation device for a battery according to this embodiment is a parameter estimation device for a battery for sequentially estimating parameters including a resistance in an equivalent circuit model of the battery based on a temperature of the battery and at least one of a voltage of the battery and a current of the battery, wherein as a resistance value of the resistance in the equivalent circuit model of the battery, a resistance value R^{T0} at a predetermined temperature T₀ is estimated, and a resistance value R(T) at a present temperature T is calculated using Expression (19) that includes the resistance value R^{T0} at the predetermined temperature T₀ and a temperature-dependent coefficient a_{R}. With the model in this embodiment, temperature information can be used in battery parameter estimation, and an error in estimate of an internal resistance caused by a temperature difference can be reduced. In detail, estimating a resistance value at a predetermined temperature contributes to better followability for a temperature difference when estimation is performed, because the resistance value at the predetermined temperature hardly changes. The parameters can thus be estimated more quickly and accurately.

The following describes examples in the case of estimating the parameters of a battery using a model having the temperature dependence represented by Expression (19). In the case of taking the temperature dependence into account, the influence of the error in measured temperature needs to be considered. The influence of which part of the battery is subjected to temperature measurement, the influence of how much measurement error the temperature sensor has, etc. need to be considered, too.

### Example 1

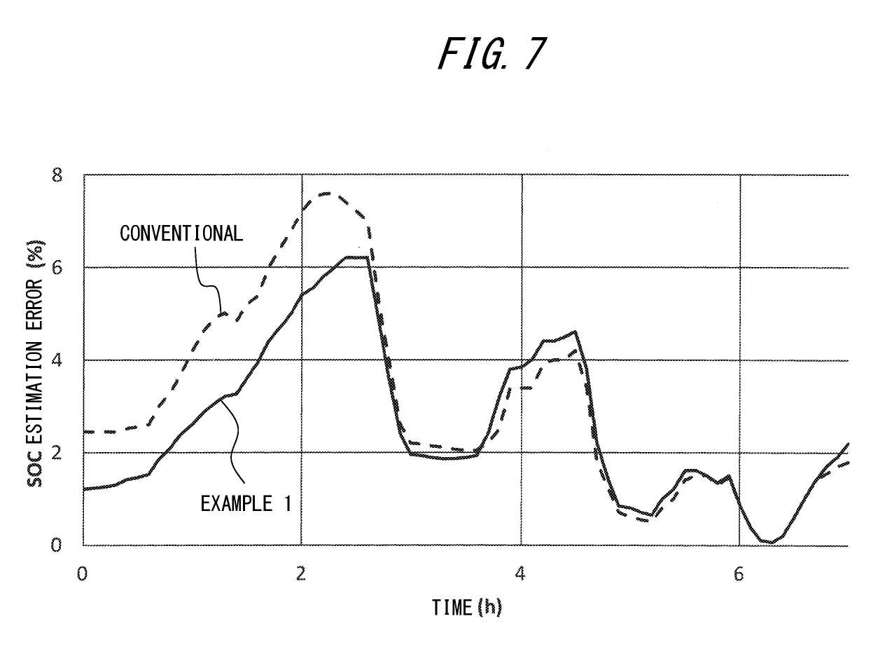

In Example 1, the temperature-dependent coefficient a_{R} is obtained beforehand using continuous-time system identification or the like, and only the resistance value R^{T0} corresponding to T₀=300 K is calculated by simultaneous estimation during actual driving. FIG. 7 illustrates the estimation error in the case of performing simultaneous estimation with the model of this example. The solid line indicates the case of applying the model of this example (Example 1), and the dashed line indicates the case of applying a conventional model. In both models, estimation can be performed with high estimation accuracy once sufficient time has passed. In an initial stage (within about 2 hours), however, the conventional model has a significant error. With the conventional model, random walk is assumed for the internal resistance when estimating the internal resistance. Accordingly, in the case where the initial estimate of the internal resistance deviates significantly, the estimate is corrected only gradually, so that convergence takes time. A major cause of such deviation of the initial estimate of the internal resistance is temperature. For example, in the case of holding the last estimate upon IGN (ignition)-OFF of the vehicle and using it as the initial estimate upon next IGN-ON, there is a possibility that, due to a temperature change during IGN-OFF, the internal resistance changes significantly and as a result deviates greatly from the initial estimate. When applying the model of this example, on the other hand, initial convergence is accelerated by the effect of taking temperature into account, and so the error is less than that of the conventional model from immediately after the estimation start.

Thus, the parameter estimation device for a battery according to Example 1 has a feature that the temperature-dependent coefficient a_{R} is a constant obtained beforehand. With the model of Example 1, estimation accuracy can be improved using temperature information, while limiting the number of parameters to be estimated to that of a conventional model.

### Example 2

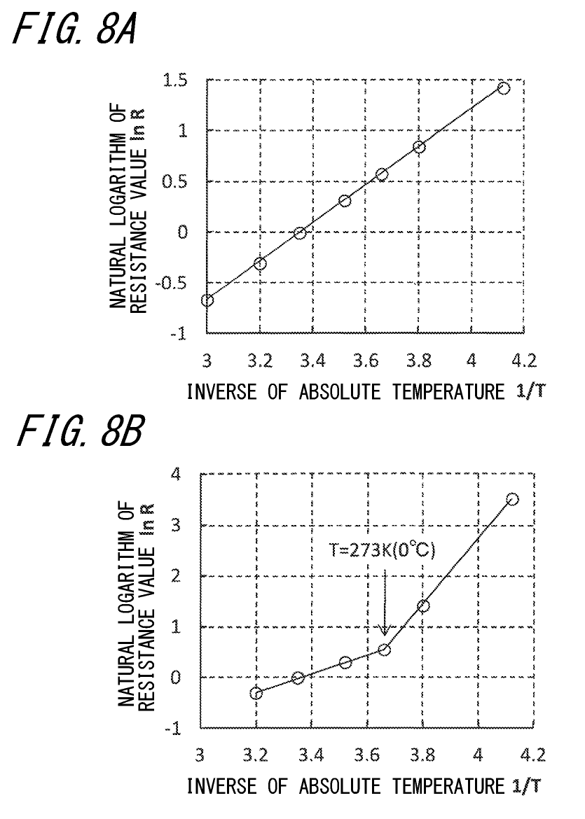

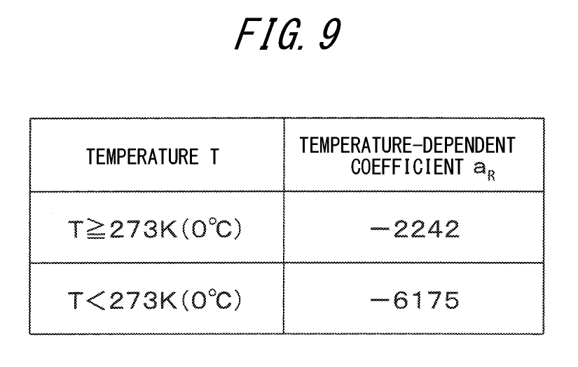

There are cases where the temperature-dependent coefficient a_{R} is not always a constant value but differs depending on temperature. In Example 2, a table indicating the relationship between the temperature-dependent coefficient a_{R} and the temperature T is obtained beforehand, and the resistance value R^{T0} corresponding to T₀=300 K is calculated by simultaneous estimation while changing the temperature-dependent coefficient a_{R} to be applied to the model with a change in temperature. The reason that the temperature-dependent coefficient a_{R} differs depending on temperature is because the battery characteristics are affected by the rate-determining process. The rate-determining process is a process with the lowest reaction rate in a chemical reaction system made up of a plurality of processes. This is the state where the rate-determining process is a bottleneck and determines the rate of the overall reaction. FIGS. 8A and 8B are each an Arrhenius plot illustrating the relationship between the internal resistance and temperature of the battery. As mentioned earlier, the relationship between a resistance value and temperature follows Arrhenius' equation. In an Arrhenius plot, the horizontal axis indicates the inverse of the absolute temperature, and the vertical axis indicates the natural logarithm of the resistance value. The vertical axis in each of the graphs in FIGS. 8A and 8B, however, indicates the ratio to, as a reference value, a resistance value at an absolute temperature of 298 K. How the rate-determining process affects the temperature-dependent coefficient is described below, with reference to FIGS. 8A and 8B. The graph in FIG. 8A has one straight line. This means that there is one rate-determining process in the temperature range presented in the graph. Since the slope of the straight line represents the temperature-dependent coefficient, the temperature-dependent coefficient is constant in the temperature range presented in the graph. On the other hand, the graph in FIG. 8B has a line bent at 0° C. This means that the rate-determining process changes at 0° C. and there are two rate-determining processes in the temperature range presented in the graph. In this case, the temperature-dependent coefficient in the temperatures lower than 0° C. and the temperature-dependent coefficient in the temperatures higher than 0° C. are different. In such a case where the temperature-dependent coefficient differs depending on temperature, it is preferable to obtain a table indicating the relationship between the temperature and the temperature-dependent coefficient beforehand and apply a temperature-dependent coefficient determined based on the table to the model. FIG. 9 illustrates an example of the table. In the table illustrated in FIG. 9, temperature-dependent coefficients are assigned to two temperature ranges. This is, however, not a limitation, and it is preferable to divide the temperatures into smaller ranges and obtain such a table that assigns a temperature-dependent coefficient to each temperature range. Moreover, the temperature-dependent coefficient is preferably represented as a function of temperature.

Thus, the parameter estimation device for a battery according to Example 2 has a feature that the temperature-dependent coefficient a_{R} is determined based on the table obtained beforehand and indicating the relationship between the temperature-dependent coefficient a_{R} and the temperature T. With the model of Example 2, the parameters can be estimated more quickly and accurately using the temperature-dependent coefficient a_{R} corresponding to the temperature, in the case where the rate-determining process changes at a temperature.

### Example 3

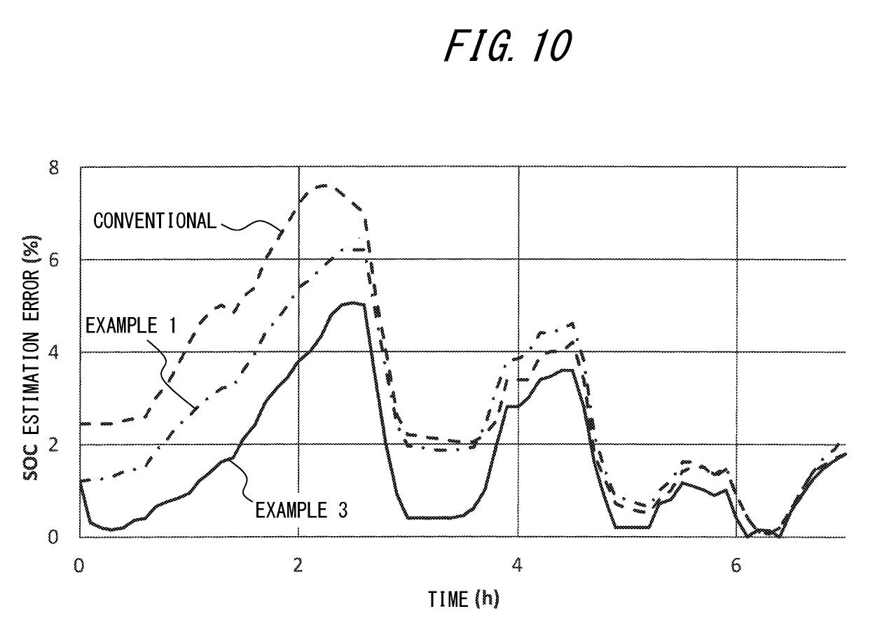

There are cases where the temperature-dependent coefficient a_{R} not only differs depending on temperature, but changes even at the same temperature due to a temporal change of the battery. In Example 3, the temperature-dependent coefficient a_{R} is not a constant and its relationship with the temperature is not obtained beforehand, and both the temperature-dependent coefficient a_{R} and the resistance value R^{T0} corresponding to T₀=300 K are calculated by simultaneous estimation. It should be noted that, in this example, the temperature-dependent coefficient is also subjected to estimation, and so the number of parameters to be estimated increases and the estimation tends to be more difficult. FIG. 10 illustrates the estimation error in the case of actually performing simultaneous estimation with the model of this example. The solid line indicates the case of applying the model of this example (Example 3), the dashed line indicates the case of applying a conventional model, and the dashed-dotted line indicates the case of applying the model of Example 1. In all models, estimation can be performed with high estimation accuracy once sufficient time has passed. In an initial stage (within about 2 hours), however, the conventional model has a significant error. When applying the model of this example, initial convergence is faster than that of the model of Example 1. This is because the temperature-dependent coefficient obtained beforehand in Example 1 is different from the actual temperature-dependent coefficient of the battery. The model of this example can more easily respond to a temporal change of the temperature-dependent coefficient.

Thus, the parameter estimation device for a battery according to Example 3 has a feature that the temperature-dependent coefficient a_{R} and the resistance value R^{T0} at the predetermined temperature T₀ are calculated by simultaneous estimation. With the model of Example 3, the parameters can be estimated more quickly and accurately even in the case where the temperature-dependent coefficient changes due to battery degradation or the like.

Although the disclosed device has been described by way of the drawings and examples, various changes or modifications may be easily made by those of ordinary skill in the art based on this disclosure. Such various changes or modifications are therefore included in the scope of this disclosure. For example, the functions included in the structural units, steps, etc. may be rearranged without logical inconsistency, and a plurality of structural units, steps, etc. may be combined into one structural unit, step, etc. and a structural unit, step, etc. may be divided into a plurality of structural units, steps, etc.

For example, although the foregoing embodiment describes the case where the Warburg impedance Z_{w} is approximated by an infinite series expansion or a continued fraction expansion, the Warburg impedance Z_{w} may be approximated by any method. The Warburg impedance Z_{w} may be approximated, for example, using an infinite product expansion.

### REFERENCE SIGNS LIST

1 battery
2 voltage sensor (terminal voltage detection unit)
3 current sensor (charge and discharge current detection unit)
4 estimation unit
41 battery equivalent circuit model
42 Kalman filter
5 charge quantity calculation unit
6 state of charge calculation unit
7 state of health calculation unit
8 temperature sensor (battery temperature detection unit)

1. A parameter estimation device for a battery for sequentially estimating parameters including a resistance in an equivalent circuit model of the battery based on a temperature of the battery and at least one of a voltage of the battery and a current of the battery,
wherein as a resistance value of the resistance in the equivalent circuit model of the battery, a resistance value at a predetermined temperature is estimated, and a resistance value at a present temperature is calculated based on the resistance value at the predetermined temperature and the present temperature.

2. The parameter estimation device for a battery according to claim 1,
wherein the resistance value at the present temperature is calculated using the following expression that includes the resistance value at the predetermined temperature and a temperature-dependent coefficient:
$$R ( T ) = {R}^{{T}_{0}} exp ( \frac{{a}_{R} ( T - {T}_{0} )}{{T}_{0} T} ) \qquad [ Math . 1 ]$$
where T is the present temperature, R(T) is the resistance value at the present temperature T, T₀ is the predetermined temperature, R^{T0} is the resistance value at the predetermined temperature T₀, and a_{R} is the temperature-dependent coefficient.

3. The parameter estimation device for a battery according to claim 2,
wherein the temperature-dependent coefficient a_{R} is a constant obtained beforehand.

4. The parameter estimation device for a battery according to claim 2,
wherein the temperature-dependent coefficient a_{R} is determined based on a table obtained beforehand and indicating a relationship between the temperature-dependent coefficient a_{R} and the temperature T.

5. The parameter estimation device for a battery according to claim 2,
wherein the temperature-dependent coefficient a_{R} and the resistance value R^{T0} at the predetermined temperature T₀ are obtained by simultaneous estimation.
